(19) United States
(12) Patent Application Publication
(10) Pub. No.: US 2026/0247625 A1
(43) Pub. Date: Aug. 20, 2026

(54) FERROELECTRIC III-NITRIDE HETEROJUNCTION DEVICES

(71) Applicant: The Regents of the University of Michigan, Ann Arbor, MI (US)

(72) Inventors: Ding Wang, Ann Arbor, MI (US); Ping Wang, Ann Arbor, MI (US); Zetian Mi, Ann Arbor, MI (US)

(21) Appl. No.: 19/162,350

(22) PCT Filed: Mar. 6, 2024
(86) PCT No.: PCT/US2024/018637

§ 371 Date: Sep. 4, 2025

Related U.S. Application Data
(60) Provisional application No. 63/450,373, filed on Mar. 6, 2023.

(51) Int. Cl. H10B 51/30; C30B 23/02; C30B 29/40; H10B 51/40; H10B 51/50; H10D 62/00; H10D 62/824

(52) U.S. Cl. CPC H10B 51/30; H10B 51/40; H10B 51/50; H10D 62/01; H10D 62/824; C30B 23/02; C30B 29/403

(57) ABSTRACT

A device includes a substrate, a template layer supported by the substrate, a ferroelectric semiconductor layer adjacent to the template layer, the ferroelectric semiconductor layer including an alloy of a III-nitride material and a Group III-B element, and a dielectric layer disposed adjacent to the ferroelectric semiconductor layer and configured to establish a ferroelectric tunneling heterojunction with the ferroelectric semiconductor layer and the template layer. The ferroelectric semiconductor layer and the dielectric layer are configured such that the ferroelectric tunneling heterojunction exhibits a conductance level in accordance with a polarization of the ferroelectric semiconductor layer.

### CROSS-REFERENCE TO RELATED APPLICATION

This application claims the benefit of U.S. provisional application entitled “Ferroelectric III-nitride Heterojunction Devices,” filed Mar. 6, 2023, and assigned Ser. No. 63/450,373, the entire disclosure of which is hereby expressly incorporated by reference.

### BACKGROUND OF THE DISCLOSURE

### Field of the Disclosure

The disclosure relates generally to Group III-nitride heterostructures.

### Brief Description of Related Technology

To alleviate the performance constraints imposed by conventional von Neumann systems in an ocean of data, new architectures employing analog in-memory computing techniques are being investigated. Two-terminal memristors, owing to their dense device structure, ability to store and process data at the same location, simple weight update scheme, and straightforward vector-matrix multiplication (VMM) in a crossbar array fashion, have been explored for neuromorphic computing, machine learning, and edge computing applications. To this end, various non-volatile memories (NVMs), including resistive memory, flash memory, phase-change memory, and magneto-resistive memory have been explored to carry out feature extraction, image processing, and neuro-inspired computing.

Ferroelectric resistive memory utilizes multi-domain polarization switching dynamics in a ferroelectric material, which has been shown to deliver fast potentiation and depression programing, symmetric and linear conductance response, and large ON/OFF conductance ratios. To harness the well-established periphery circuitry and increase integration density, however, it is desired to integrate ferroelectric memory arrays with mainstream semiconductor technology, which significantly narrows down the materials available.

The discovery of ferroelectricity in HfO₂-based materials has rejuvenated the interest in ferroelectric memory with both front-end-of-line and back-end-of-line compatibility. However, two terminal resistive memories using HfO₂-based materials suffer from low ON/OFF ratios, wake-up effect and significant imprint oscillations and retention loss. Although recent studies have shown that HfO₂-based field effect transistors are much less affected by those limitations, two-terminal memristors offer the advantages of significantly reduced device area and operation power and, therefore, have remained a subject of intensive study.

Sc-alloyed III-nitrides (ScAlN, ScGaN) are a new class of ferroelectric materials that have been found to exhibit giant remnant polarization and superior thermal stability. The wide processing temperature window and the approximation of the lattice with other nitride materials promise good compatibility and seamless integration with existing processing technologies. In addition, the wake-up effect and imprint are reported to be weak for epitaxial ScAlN films. Given those features, a few memristor demonstrations based on ScAlN have been reported. However, the ScAlN layers employed are thick (greater than 20 nm), which causes high operation voltages and potentially scalability problems.

### SUMMARY OF THE DISCLOSURE

In accordance with one aspect of the disclosure, a device includes a substrate, a template layer supported by the substrate, a ferroelectric semiconductor layer adjacent to the template layer, the ferroelectric semiconductor layer including an alloy of a III-nitride material and a Group III-B element, and a dielectric layer disposed adjacent to the ferroelectric semiconductor layer and configured to establish a ferroelectric tunneling heterojunction with the ferroelectric semiconductor layer and the template layer. The ferroelectric semiconductor layer and the dielectric layer are configured such that the ferroelectric tunneling heterojunction exhibits a conductance level in accordance with a polarization of the ferroelectric semiconductor layer.

In accordance with still yet another aspect of the disclosure, a method of fabricating a device includes providing a substrate, forming a template layer supported by the substrate, implementing a non-sputtered, epitaxial growth procedure to form a ferroelectric semiconductor layer, the ferroelectric semiconductor layer being supported by, and in contact with, the template layer, the ferroelectric semiconductor layer including an alloy of a III-nitride material, the non-sputtered, epitaxial growth procedure being configured to incorporate a group IIIB element into the alloy of the III-nitride material, and controlling formation of a dielectric layer adjacent the ferroelectric semiconductor layer, the dielectric layer being disposed and configured to establish a ferroelectric tunneling heterojunction with the ferroelectric semiconductor layer and the template layer.

In accordance with another aspect of the disclosure, a method of operating a device including a ferroelectric tunneling junction, the device having a plurality of polarization states, includes applying a first write voltage level across the device to switch the device to a first intermediate polarization state of the plurality of polarization states, applying a second write voltage level across device to switch the device to a second intermediate polarization state of the plurality of polarization states, and applying a read voltage level across the device to determine whether the device exhibits a first conductance level indicative of the first intermediate polarization state or a second conductance level indicative of the second intermediate polarization state.

In connection with any one of the aforementioned aspects, the devices and/or methods described herein may alternatively or additionally include or involve any combination of one or more of the following aspects or features. The dielectric layer and the ferroelectric semiconductor layer are sufficiently thin to establish the ferroelectric tunneling heterojunction. The ferroelectric semiconductor layer has a thickness less than about 10 nm. The dielectric layer has a thickness less than about 10 nm. The ferroelectric semiconductor layer and the dielectric layer are configured such that the ferroelectric tunneling heterojunction exhibits partial polarization switching. The partial polarization switching establishes a plurality of non-zero conductance levels in addition to an off state of the device. The dielectric layer includes an oxide material. The oxide material is a non-native oxide of the ferroelectric semiconductor layer. The oxide material is a native oxide of the ferroelectric semiconductor layer. The dielectric layer includes a non-oxide material. The ferroelectric semiconductor layer is in contact with the template layer. The device further includes a driver circuit coupled to the ferroelectric tunneling heterojunction and configured to apply non-linear write voltage levels across the ferroelectric tunneling heterojunction to establish a plurality of polarization states of the ferroelectric tunneling heterojunction, the plurality of polarization states including multiple intermediate polarization states. Controlling formation of the dielectric layer includes depositing an oxide layer having a thickness sufficiently thin to establish the ferroelectric tunneling heterojunction. Controlling formation of the dielectric layer includes limiting exposure to an ambient such that a native oxide layer is grown to a thickness sufficiently thin to establish the ferroelectric tunneling heterojunction. Controlling formation of the dielectric layer includes depositing a non-oxide layer having a thickness sufficiently thin to establish the ferroelectric tunneling heterojunction. The non-sputtered, epitaxial growth procedure is configured such that the ferroelectric semiconductor layer has a thickness of less than about 10 nm. Implementing the surface treatment procedure includes annealing the ferroelectric semiconductor layer. The non-sputtered, epitaxial growth procedure is implemented under a nitrogen-rich condition. The method further including generating the first write voltage level or the second write voltage level from a linear control voltage. Applying the first write voltage level includes reaching the first intermediate polarization state by switching from one of at least eight polarization states of the plurality of polarization states to the first intermediate polarization state. Applying the first write voltage level includes driving a potentiation response of the ferroelectric tunneling junction device. Applying the first write voltage level includes driving a depression response of the ferroelectric tunneling junction device.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1 depicts ferroelectricity in ultrathin ScAlN films grown on GaN, including a) a schematic illustration of a capacitor device including an ultrathin single-crystalline ScAlN and an oxide layer, in which, due to the high oxygen affinity of Sc and Al, a thin oxide layer is formed on the top of ScAlN, in accordance with one example, b) a HAADF-STEM image of the heterostructure indicating an oxide layer of about 4 nm and a ScAlN layer of 5-6 nm, c) a magnified STEM image at the ScAlN/GaN interface showing atomic sharp contrast, d) NBED patterns acquired from different regions in b): (i) the oxide layer, showing non-crystalline diffraction pattern, (ii) ScAlN layer and (iii) GaN layer, showing a wurtzite structure, in which the scale bar is 2 nm⁻¹, e) HAADF-STEM and corresponding EDS element maps of the heterostructure. Increased oxygen signal is detected near the surface, f) PUND pulse trains and corresponding current responses, g) a graphical plot of voltage-dependent PUND results with a pulse width and delay of 10 μs, revealing a saturated remnant polarization >16 μC/cm², in which the inset shows the displacement current by subtracting non-switching current in f), and h) a graphical plot of a butter-fly shape capacitance-voltage curve of the heterostructure measured at 1 MHz with an AC voltage of 200 mV.

FIG. 2 depicts an electrical characterization of a nitride memory device (or memristor) in accordance with one example at room temperature, including a) schematic illustrations of the nitride memory device and band profiles showing the ferroelectric polarization modulated potential energy barrier, b) a graphical plot of current hysteresis loops measured using pulse trains shown in the inset, in which the device is preset to the ON(OFF) state by a −11 V (+6.5 V) pulse, followed by staircase-like rectangular write pulses between −11 V and 6.5 V and read pulses of −3 V after each write pulse, c) a graphical plot of the current rectifying ratio extracted from the negative branch in b), d) a graphical plot of ON/OFF operation of 20 devices, and graphical plots of the (e) endurance and (f) retention properties of the memristor, with rectangular write pulses of −8 V and 6 V and read voltage of −3 V, in which the pulse width for pre-set, write and read pulses were 8 ms, 8 ms, and 0.16 s, respectively.

FIG. 3 depicts example multi-state and convolution operation of nitride memristors, including graphical plots of a) multi-state operation by incremental pulses from −8 V to −8.35 V with a step of −50 mV and read voltage of −3 V, in which the pulse width is 8 ms, b) retention of the 8 states up to 200 s, c) I-V curves of the 8 conductance states, showing non-linear I-V behavior, d) fitting of the I-V curves in different states using an exponential function on the −2 to −3 V window, and e) fitting parameters against the device state, and including f, g) schematic and graphical illustrations of a logarithmic driver that maps linear input voltage to non-linear inputs for the non-linear nitride memristors, such that, by properly choosing the fitting parameters, linear effective conductance can be established for analog computing, h) a depiction of gray-scale image inputs for convolution operations, in which the luminance of each pixel is encoded into voltage pulses from −2.05 V to −2.98 V according to g) and weighted outputs based on the 8 conductance states are shown accordingly, and i) an image convolution operation using the ferroelectric nitride memory for three different kernels, in which a gray-scale image with 100×100 pixels is used as the input image, and three 3×3 kernel operations (mean, edge, and sharpen) are performed as examples.

FIG. 4 depicts weight update characteristics of an example ferroelectric nitride memristor for neuromorphic computing and pattern recognition based on a two-layer MLP neural network, including graphical plots of a) 7-bit potentiation and depression responses of the memristor to identical set/reset (blue, −7.8 V for potentiation and 2.7 V for depression) and staircase set/reset (green, from −7.6 V to −8.24 V in a 5 mV step for potentiation and from 1.9 V to 3.564 V in a 13 mV step for depression) pulse trains, in which the read pulse after each write pulse is-3 V and all pulse widths are 8 ms, b) reproducible and uniform analog switching behavior over multiple cycles and on different devices under staircase pulse trains, c) cycle-to-cycle variation and device-to-device variation characteristics of the memristor collected from 20 cycles and 10 devices, and d) a comparison of simulated accuracies of the two-layer MLP based on ideal device (black, 128 states, on/off ratio of 50, perfect linearity), and based on nitride memristor with non-linearity property (blue) and further with cycle-to-cycle variation and device-to-device variation (green), in which the best recognition accuracy of 92.9% was achieved for ferroelectric nitride memristor with non-linearity and cycle-to-cycle/device-to-device variations.

FIG. 5 depicts a cross-sectional, schematic view of a memory device having a ferroelectric tunneling heterojunction with an epitaxially grown ferroelectric III-nitride alloy layer in accordance with one example.

FIG. 6 is a flow diagram of a method of fabricating a heterostructure having an epitaxially grown ferroelectric III-nitride alloy layer in accordance with one example.

FIG. 7 depicts a flow diagram of a method of operating a device having a ferroelectric tunneling junction in accordance with one example.

The embodiments of the disclosed devices and methods may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

Devices with a ferroelectric tunneling heterojunction are described. A dielectric layer and a ferroelectric semiconductor layer of the disclosed devices are configured to establish the ferroelectric tunneling heterojunction. For instance, the dielectric layer and the ferroelectric semiconductor layer may be sufficiently thin to establish the ferroelectric tunneling heterojunction. In some cases, the ferroelectric tunneling heterojunction may be configured to implement a memory device, such as an ultrathin nitride-based ferroic memory. As described herein, the ferroelectric tunneling junction may lead to large ON/OFF ratios useful in, for instance, analog in-memory computing applications. To those and other ends, the ferroelectric semiconductor layer and the dielectric layer are configured such that the ferroelectric tunneling heterojunction exhibits one of a plurality of conductance levels in accordance with a polarization of the ferroelectric semiconductor layer. As described herein, the disclosed devices may be capable of exhibiting a large number of conductance levels. The ferroelectric tunneling heterojunction may thus support multiple intermediate states corresponding with distinct conductance levels based on partial polarization. Methods for fabricating and operating such devices are also described.

With the multiple conductance levels, the disclosed devices may be configured to implement analog computing and other resistive switching operations, e.g., as a ferroic heterojunction memory device. To this end, the disclosed devices may include an ultrathin nitride ferroelectric material, e.g., ScAlN, as the barrier layer. As described herein, examples of ferroelectric switching were confirmed in devices having a sub-10-nm thick ScAlN layer via positive-up negative-down (PUND) and capacitance-voltage (C-V) measurements. High ON/OFF ratios (10⁴-10⁵), high uniformity, excellent retention (>10⁵ s) and good cycling endurance (>10⁴) in the nitride-based ferroelectric junction were also demonstrated via the incorporation of an oxide capping layer. Due to significant scaling down of thickness, the read/write voltages of the example devices were reduced to less than 3 V and 8 V, which is close to hafnia-based ferroelectric junctions. The nitride-based memristor devices were also shown to provide programmability to enable multistate operation and linear weight updates in connection with, for instance, image processing, with high accuracy. The example devices were also employed in artificial neural network (ANN) operations based on the weight update characteristics of the disclosed nitride memory device, thereby demonstrating the operation of the nitride-based memory devices for accurate analog in-memory computing. The robust and programmable operation of the nitride ferroelectric memory devices thus support a wide variety of analog computing applications, power-efficient data storage, and advanced computing platforms. For instance, as described herein, the disclosed devices are capable of achieving precise VMM operation and image processing.

Sc alloyed III-nitride semiconductors have emerged as promising ferroelectrics with wide and tunable bandgap, large switchable polarization and high coercive field. The large switchable polarization provides more design freedom for field-charge coupling while the high coercive field provides a large memory window when integrated with field-effect transistors. Advancements in the deposition methods have opened the pathway to integrating Sc-III-N nitride ferroelectrics with mainstream semiconductors including silicon and GaN. However, the large switching voltages due to limited thickness scaling down have posed challenges on the practical applications of nitride ferroelectrics. On the other hand, unlike hafnia-based ferroelectrics, which tend to have competing phases, ferroelectric wurtzite phase is the energetically-stable crystalline phase in low-Sc-content Sc-III-N at room temperature, making it highly possible to maintain ferroelectric order in nitride ferroelectrics even at extremely reduced dimensionality. Therefore, the examples described herein usefully explore scaling down the thickness of nitride ferroelectrics.

The Sc content, thickness, and other characteristics of the wurtzite-phase ScAlN layers of the disclosed devices and methods may differ from the examples described herein. For instance, the Sc content, x, may vary from about 0.05 to about 0.5 in some cases. The Sc content may fall outside this range in other cases.

The disclosed devices and methods may include one or more elements, aspects, or other features described in International Application No. PCT/US2022/028365, filed May 9, 2022, and entitled “Epitaxial Nitride Ferroelectronics”, the entire disclosure of which is hereby incorporated by reference.

The ferroelectric semiconductor layer is supported by, and in contact with, a template layer. The template layer may form a variety of heterostructure arrangements and corresponding devices, including, for instance, capacitors and memristors (e.g., synaptic memristors), examples of which are described below. Although described in connection with examples in which the template layer is composed of GaN, alternative or additional materials may be used, including, for instance, other semiconductor materials, such as silicon or other non-nitride semiconductor materials. In still other cases, the template layer may be composed of, or otherwise include, alternative or additional materials, including, for instance, metal materials. For instance, the template layer may be composed of, or otherwise include, a CMOS compatible metal, such as molybdenum. The ferroelectric semiconductor layer may be single-crystalline or monocrystalline despite a polycrystalline nature of the metal layer. A surface of the metal layer may be oriented in a plane that matches the atomic arrangement of a wurtzite (0001) plane of the single-crystalline III-nitride alloy layer.

Although described in connection with examples of epitaxially grown ScAlN layers, the disclosed heterostructures, devices and methods may be applied to a wide variety of III-nitride alloys. The disclosed heterostructures, devices and methods may thus include or involve the incorporation of scandium into other III-nitride wurtzite structures. For instance, the disclosed heterostructures, devices and methods may include or involve one or more epitaxially grown ScAlGaN layers, ScAlInN layers, ScGaN layers, or ScInN layers. The configuration, construction, fabrication, and other characteristics of the heterostructures may also vary from the examples described. For instance, the heterostructures may include any number of epitaxially grown layers of ferroelectric and non-ferroelectric nature.

The disclosed heterostructures, devices and methods are also not limited to III-nitride alloys including scandium. For instance, the III-nitride alloys may include additional or alternative group IIIB elements, such as yttrium (Y) and lanthanum (La).

Compared with sputter deposition, molecular beam epitaxy (MBE) and other non-sputtered epitaxial growth procedures provide better thickness and crystal quality control. Although some aspects of the disclosed methods are accordingly described in connection with MBE growth procedures, additional or alternative non-sputtered epitaxial growth procedures may be used. For instance, metal-organic chemical vapor deposition (MOCVD) and hydride vapor phase epitaxy (HVPE) procedures may be used. Still other procedures may be used, including, for instance, pulsed laser deposition (PLD) procedures and atomic layer deposition (ALD) procedures.

Although described in connection with examples in which the III-nitride alloy is grown on a GaN layer, the disclosed heterostructures, devices and methods are not limited to growth on GaN layers. Other semiconductor materials may be used, including, for instance, silicon. Non-semiconductor materials may also be used. For instance, a variety of metals may be used, including, e.g., Mo, Al, Pt, Ti, Fe, Cu, and Ni. Other characteristics of the template layer may also vary. For instance, the metal layer may be single-crystalline (or monocrystalline) or polycrystalline.

III-N semiconductors with wz-phase (space group P6₃mc) lattices have the strongest polarization along the c-axis direction. Therefore, growing along <0001> direction maximizes the remnant polarization in ferroelectric nitrides. However, growth along alternative or additional directions may be implemented in other cases.

Described below are a number of examples having a heterostructure grown using a Veeco GENxplor MBE system with a base chamber pressure of 10⁻¹¹ Torr on commercial n-GaN templates. Active nitrogen (N⁺, 7N purity) species were provided by a Vecco RF UNI-Bulb plasma source, while gallium (Ga, 7N purity), aluminum (Al, 6N5 purity), scandium (Sc, 5N purity, from American elements), and silicon (Si, 6N purity) sources were supplied using Knudsen effusion cells. A 200-nm-thick Si-doped n⁺-GaN layer was grown as a bottom contact layer, after which a ScAlN layer having a thickness of about 9 nm and a nominal Sc content of 30% was grown under nitrogen rich condition. Further details regarding the growth conditions may be found in the above-referenced patent publication.

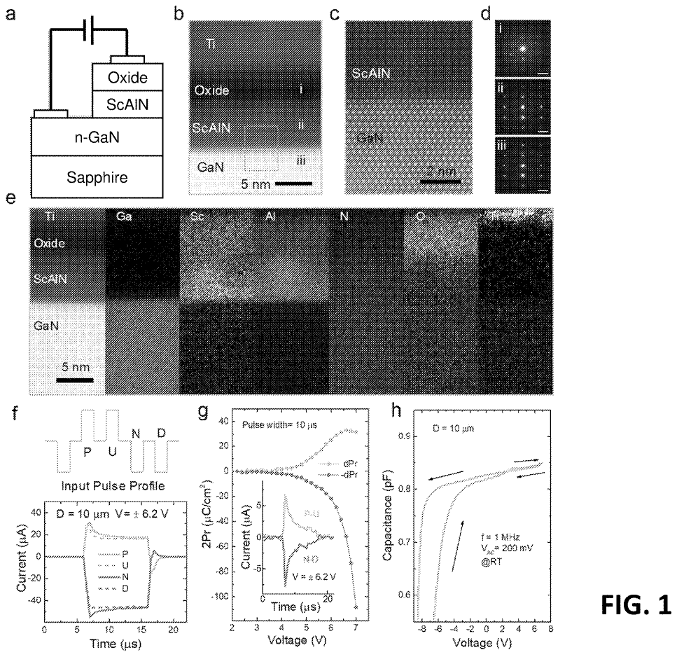

FIG. 1, part (a), depicts the schematic of a metal/ScAlN/n-GaN capacitor device used to demonstrate the ferroelectricity of ultrathin ScAlN layers of the disclosed devices. Due to the high oxygen affinity of Sc and Al, a thin oxide layer naturally formed at the surface, which appeared as the dark contrast region in the high-angle annular dark field scanning transmission electron microscope (HAADF-STEM) image (FIG. 1, part b). Highly ordered atomic stacking sequence with a wurtzite structure are observed at the ScAlN/GaN interface, revealing the high-quality of the MBE-grown ScAlN film (FIG. 1, part c). The single crystalline wurtzite structure of ScAlN and GaN as well as the non-crystalline structure of the oxide layer are further confirmed by nano-beam electron diffraction (NBED) patterns as shown in FIG. 1, part (d). A HAADF-STEM image combined with corresponding elemental analysis (EDS mapping, FIG. 1, part e) indicates the oxide layer has a thickness of about 4 nm while the ScAlN layer has a thickness of about 5 to 6 nm.

The oxidation process may be controlled by modulating the total exposure time, e.g., using glove boxes with different gases or by controlled oxygen plasma treatment. As described below, the oxide layer may function as an extended barrier to enhance the rectifying ratio of the memristor device.

Parts (f) and (g) of FIG. 1 show the PUND results using 10 μs short pulses performed on 10-μm-diameter capacitors. The contribution of the ferroelectric displacement current can be clearly observed. A saturated remnant polarization (Pᵣ) of greater than 16 μC/cm² was exhibited. The device thus exhibits both giant ferroelectric polarization and saturated switchable polarization in crystalline ScAlN in the sub-10 nm regime. The reduction in remnant polarization compared with thick ScAlN is mainly due to the oxide layer at the surface, which forms a ferroelectric-dielectric bilayer structure and amplifies the effect of the depolarization field during thickness-scaling. The butterfly-like hysteresis in the C-V loop, which is characteristic of ferroelectric capacitors, is also depicted in FIG. 1, part h. The extracted relative permittivity at zero bias is approximately 10.4, which is smaller than bulk values due to increased contribution from the surface oxide layer.

In other cases, the thicknesses of one or both of the oxide capping layer and the ferroelectric ScAlN layer may be lower. Further scaling-down of the nitride-based ferroelectric devices described herein may thus be achieved.

Examples of memory cell devices having ferroelectric junctions were also fabricated. The memory cell devices have upper electrode diameters ranging from 0.8 to 20 μm. Unless otherwise mentioned, the measurement results presented herein are based on the memory cell devices having a diameter of 5 μm.

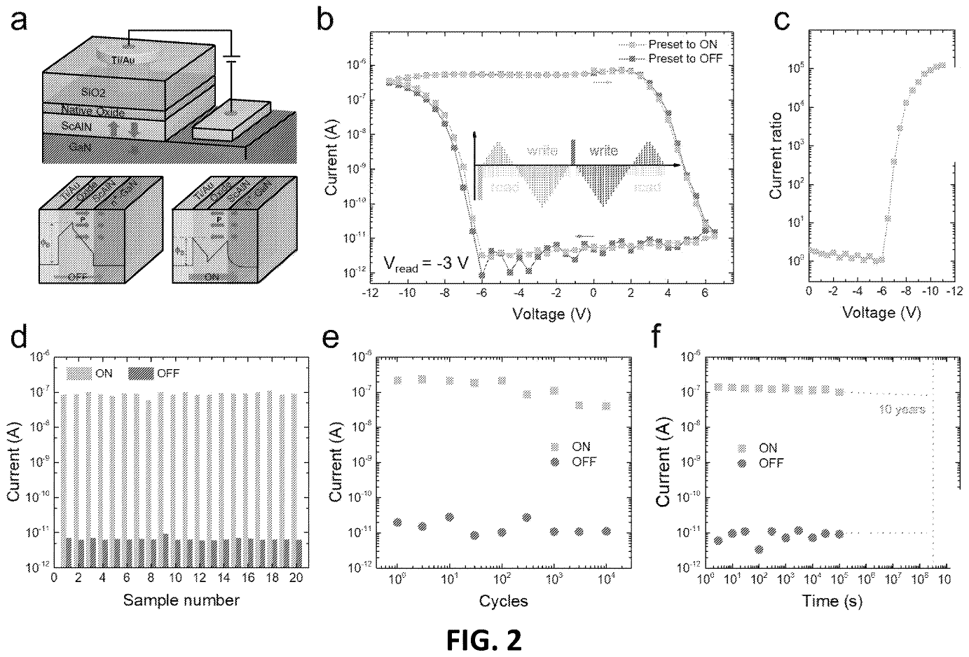

FIG. 2, part (a), depicts schematic views of the structure and operation of a nitride-based memory device in accordance with one example. As described herein, the memory device is configured for resistive switching. Due to the existence of an oxide layer, the ferroelectric polarization charge at the oxide/ScAlN interface causes a giant modulation effect on the total barrier height, significantly contributing to large ON/OFF operations. In this case, polarization pointing down leads to a higher total barrier and thus OFF operation, while polarization pointing up results in a lower barrier and ON operation. The depletion region in the semiconductor side is negligible as the doping concentration of the n-GaN bottom electrode is sufficiently high (e.g., greater than 2×10¹⁹ cm⁻³), implied by the small capacitance hysteresis near zero bias (see FIG. 1, part h). The trapped charge at the oxide/ferroelectric and ferroelectric/semiconductor electrode interface may also lead to a reduction of the depletion region.

The nonvolatile conductance switching in the nitride memory is demonstrated by the clear hysteretic variation of the read current, as shown in FIG. 2, part (b). The pulse trains used are shown in the inset. Negative pulses set the polarity to upward direction, consequently the ON state, while positive pulses set the polarity to downward direction and corresponds to the OFF state, consistent with the band schematics in FIG. 2, part (a). By pre-programming the device to OFF state and gradually switching to the ON state, a giant ON/OFF ratio approaching 10⁵ is demonstrated, as shown in FIG. 2, part (c). Part (d) of FIG. 2 further shows the ON/OFF currents of 20 different devices with write pulses of −8 V and +6 V, and read pulses at −3 V. All measured devices exhibit high ON/OFF ratios larger than 10⁴, suggesting good reproducibility and uniformity.

Parts (e) and (f) of FIG. 2 depict the endurance and retention properties of the device. ON/OFF ratios greater than 10³ were still obtained after 10⁴ bipolar switching cycles, with decreasing ON current possibly due to pinned domains parallel to the polarity of the substrate. The endurance obtained is somewhat lower than for fluorite-based ferroelectrics, yet the endurance is sufficient for many applications, including, for instance, an inference engine. Moreover, the device shows outstanding retention resistance, with only less than 20% degradation in ON current after 10⁵ seconds, which outperforms hafnia-based devices. Retention tests at elevated temperatures were also performed. The reliability exhibited in these tests support the use of the disclosed ferroelectric nitride memory devices in a wide variety of non-volatile memory and advanced computing applications.

The ferroelectric junction of the disclosed devices may also be used to implement ferroelectric memristors, in which multiple conductance levels can be established via partial polarization switching. The disclosed memristors are thus well suited for high-density data storage applications and advanced computing architectures. The coupling between polarization and resistance in the ScAlN/GaN heterostructure establishes the feasibility to change the polarization, and thus the resistance, gradually.

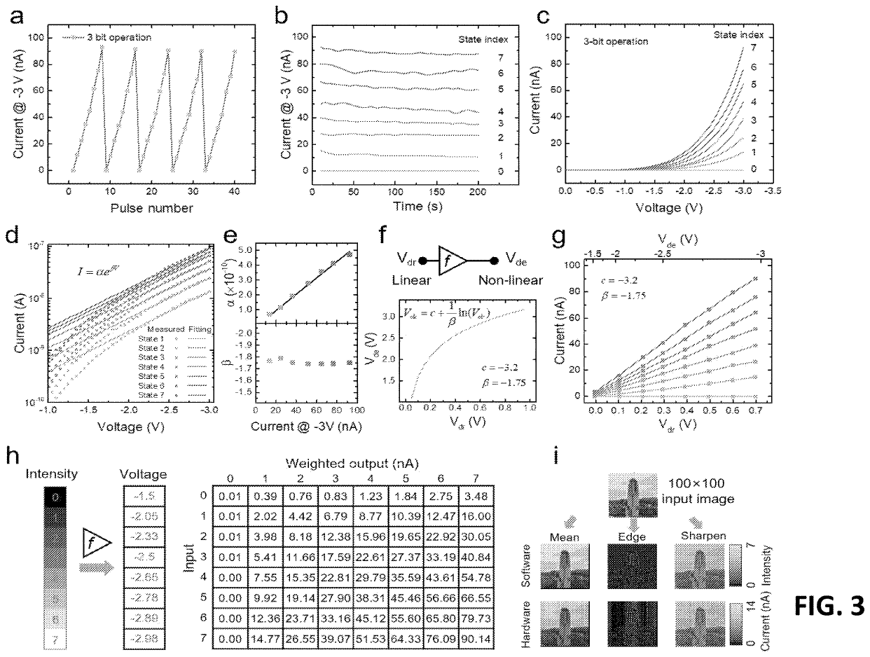

FIG. 3, part (a), depicts the operation of an example nitride-based memristor that uses an incremental voltage pulse scheme to establish eight clear, distinguishable conductance states. The conductance levels can be restored after multiple program/reset operations, and remain stable up to 200 seconds (see FIG. 3, part b). In addition to the reliability shown, the device exhibits a nonlinear I-V characteristic in all conductance states (see FIG. 3, part c), which is useful for suppressing sneak path currents and cross-talk in selector-free crossbar arrays. Unlike redox or filament based resistive memory devices, the example memristor device can be switched to separate or distinct analog states without any initial forming or activation step, which not only reduces the overall operation voltage, but also establishes that the device and the circuits can be readily used in arrays without electrical pretreatment, a key issue for memory arrays that may otherwise limit the stability and accuracy of the conductance state. These results, in combination with the compatibility of nitride ferroelectrics with mainstream semiconductor technologies, make the disclosed memristor useful for compact non-volatile memory architectures and other applications.

FIG. 3 depicts the implementation of convolution operations by the disclosed memristor. In convolution operations based on resistive crossbars, the output can be obtained from the current sums of the products of the input voltage vector and the device conductance, which involves electrical programmability and I-V linearity. To demonstrate the implementation of convolution operations using the nonlinear nitride memristor, a virtual logarithmic line driver may be used, which converts the linear input signal into nonlinear amplitude-programmed pulses to generate linear conductance outputs from the nonlinear nitride memristor.

Parts (d) and (e) of FIG. 3 show the fitting results of the I-V characteristics using an exponential function, which is typical for thermal and tunneling based conduction. Almost constant ß and linear a values over each conductance level are obtained for all the conductance states in the [−2, −3.0] V and [2, 90] nA range, as shown in FIG. 3, part (e). A mapping function, as shown in FIG. 3, part (f), may be utilized to scale the non-linear device voltage V_{de} to a linear drive voltage V_{dr} with β=−1.75 and c=3.2 as an example. FIG. 3, part (g), depicts the mapping results, where linear effective conductance is achieved for all conductance levels. In some cases, the logarithmic line driver may be implemented with nonlinear drive circuits, such as p-n junctions or Schottky barrier diodes.

FIG. 3 also depicts an example implementation of linear vector-matrix-multiplication (VMM) by the disclosed memristors for image convolution processing. In this case, 3-bit grayscale images are first converted into voltage pulses according to the mapping methodology in FIG. 3, part (g). Accordingly, 3-bit conductance levels, i.e., 8 states, are then used as synaptic weights. FIG. 3, part (h), shows the weighted output map for each input pixel intensity, which may be regarded as the multiplication results of 1-by-1 vectors with 1-by-1 matrixes (pixel intensity times weight). An error standard deviation of 2.3% was exhibited.

Based on the scheme described above, convolution operations were implemented using three 3×3 kernels, i.e., mean, edge and sharpen, for a gray-scale input image with 100×100 pixels. Nine devices were first programmed to different conductance levels according to the kernel weights, and the voltage pulses converted from the intensity values of each pixel of the image are sequentially applied to every device. The weighted output currents from each device are collected separately as a multiplication operation output, while the accumulation operation may be implemented in software. This example ignores the inaccuracies introduced by the logarithmic driver and the differential readout circuits, but is sufficient for demonstration purposes. FIG. 3, part (i), depicts the convolution results from a pure software calculation and from the current outputs of the nitride-based memristors, showing high convolution accuracy. The implementation of high accuracy VMM operations may thus be achieved using an array of three different devices, where current sums were readout directly from hardware. These results establish that ferroelectric nitride memristors may be used for convolution operations for applications such as image processing and feature extraction.

In the examples described above, only eight conductance states (or polarization states) are utilized. The disclosed devices may be configured to exhibit a lesser or greater number of states in other cases. A greater number of states may be useful, for instance, in connection with ANNs computing in the analog regime, in which linear, symmetric potentiation and depression conductance response with tens of conductance states may be involved to accelerate the training process effectively. In such cases, minimizing the cycle-to-cycle and device-to-device variations may be useful.

In one example, the disclosed memristor may accordingly configured for operation with 128 states (seven bit operation). As described below, two pulse schemes, namely identical pulse scheme and amplitude-incremental pulse scheme, were implemented to test the symmetry and linearity during 128-state (7-bit) potentiation and depression operations. For the identical pulse scheme, a −7.8 V pulse is used for potentiation and a 2.7 V pulse is used for depression. For the incremental pulse scheme, the amplitude of the pulses is increased from −7.6 V to −8.24 V in a 5 mV step for potentiation, and from 1.9 V to 3.564 V in 13 mV step for depression, respectively. In this example, the read voltage is −3 V and the read/write pulse widths are fixed at 8 ms for simplicity.

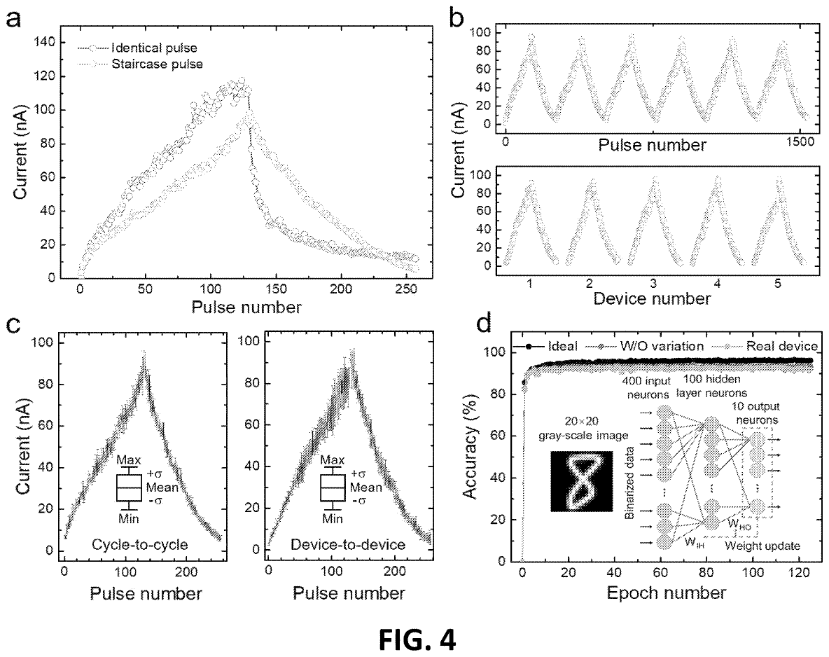

As shown in FIG. 4, part (a), the second scheme delivers much more linear weight update characteristics, which is then adopted for ANN operation. The current for each state is relatively low, which may cause increased latency for single-device readout, but will not matter much for large-scale computing arrays, where current output from multiple devices are combined for accumulated readout. The cycle-to-cycle and device-to-device variation characteristics are further investigated in parts (b) and (c) of FIG. 4. No significant degradation is observed during repeated pulse operations (FIG. 4, part b). The average cycle-to-cycle variation (standard error) is further estimated to be less than 2.2% based on 20 repeated cycles (FIG. 4, part c). Ten different devices are measured to evaluate the device-to-device variation with results from the first five devices shown in FIG. 4, part (b). The device-to-device variation is found to be relatively larger than the cycle-to-cycle variation, with maximum variation less than 6% and an average device-to-device variation of 3.1%. This relatively large device-to-device variation, however, is unlikely to cause significant performance degradation because the ANN operation may have self-adaptation to such static variation. Modifications of the processing steps and the weight-update scheme may also be used to tailor the disclosed nitride-based memristors for ANN operation, thereby improving uniformity and reliability.

Based on above weight update results, the disclosed nitride memristors are used to implement an application in which a trained two-layer multilayer perceptron (MLP) neural network is tasked to for image classification. For this example, handwritten images from the Modified National Institute of Standards and Technology database (MNIST) are to be classified. An illustration of the network is shown in the inset of FIG. 4, part (d). While the implementation results may vary depending on the neural network structures employed, this example tool supports a comparison with other memory devices. During operation, the nonlinearity factors are set to 0.22 and - 1.69 for potentiation and depression with cycle-to-cycle variation of 2.2% and device-to-device variation of 3.1%. The weight values are mapped to the conductance range shown in FIG. 4, part (c). As shown in FIG. 4, part (d), even though the device is still in its infancy, a recognition accuracy of 92.9% (96.2% for ideal device) was achieved based on the realistic weight update characteristics of the nitride ferroelectric memristor. These results already outperform most analog synaptic devices and are comparable to state-of-the-art ferroelectric transistors. Operation without considering cycle-to-cycle and device-to-device variations was also performed and yielded an increased recognition accuracy of 94.1%, implying that both the linearity of the weight update and the stability of the established states may be optimized to further improve the overall accuracy. Nevertheless, the operation of the MLP-based neural network confirmed that the disclosed ferroelectric devices may be employed for implementation of accurate in-memory computing architectures.

Described above are examples of devices that exhibit ferroelectric and analog resistive switching in an ultrathin ferroelectric oxide/ScAlN/GaN heterojunction. PUND and C-V measurements were conducted to explore the ferroelectricity in the sub-10 nm ScAlN layer. With the help of a thin oxide capping layer, the heterostructures of the example devices exhibited great potential for nonvolatile memory with superior ON/OFF ratios, high uniformity, good retention and modest cycling endurance. In addition, the disclosed nitride memristor are capable of providing programmability to enable multistate operation and linear analog computing, as well as image processing with high accuracy, where the nonlinearity of the I-V characteristics and the low operation conductance may be useful in selector-free crossbars with high power efficiency. Neural network implementation based on the weight update characteristics of the ferroelectric nitride memory also yielded high image recognition accuracy. The robust ferroelectricity in the sub-10-nm ScAlN layer supports further scaling down the thickness and operation voltage of nitride ferroelectrics for energy efficient applications. The non-volatile multi-level programmability and analog computing capability of the disclosed devices may fill the gap between performance and compatibility in conventional ferroelectrics, and allow for constructing advanced memory/computing architectures based on nitride ferroelectrics, including homogenous and hybrid integrated functional edge devices beyond silicon.

Although described herein in connection with applications involving memristors and other memory devices, the disclosed heterostructures may be used in a variety of applications, including those involving the heterogeneous integration of III-N architectures and CMOS technology. For instance, the nitride-based ferroelectrics of the disclosed heterostructures may be integrated in various other devices, systems, or applications, including a variety of advanced computing applications.

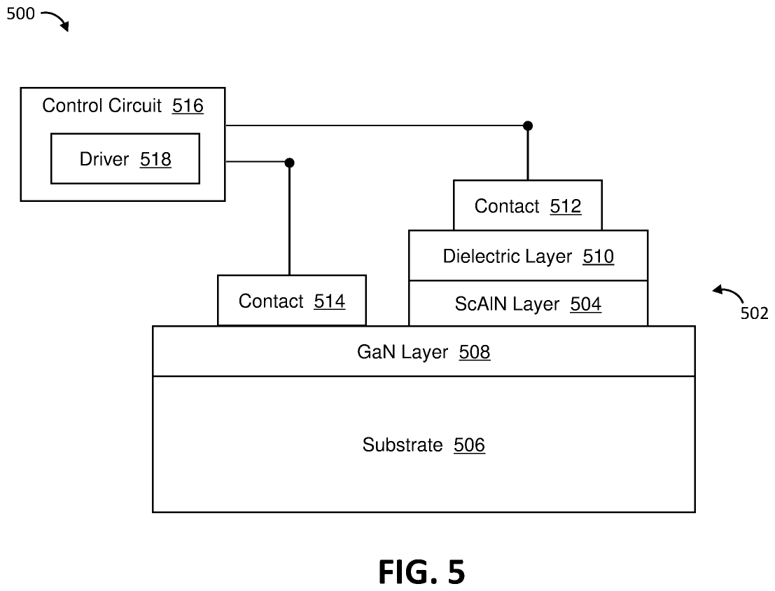

FIG. 5 depicts a memory device 500 having a heterostructure 502 with a ferroelectric tunneling junction in accordance with one example. The heterostructure 502 includes a ferroelectric semiconductor layer 504 having a thickness as described herein. In this example, the device 500 is a two-terminal device. In some cases, the device 500 is configured or operated as a memristor. In other cases, the device 500 may include any number of alternative or additional terminals, layers, or other structures. For instance, the device 500 may be integrated with any number of other devices.

The device 500 includes a substrate 506 and a heterostructure 502 supported by the substrate 506. The substrate 506 may be composed of, or otherwise include, sapphire. Additional or alternative substrate materials may be used, including, for instance, silicon, silicon carbide, bulk GaN, bulk AIN, GaN templates, and AIN templates. The substrate 506 may be uniform or composite.

The heterostructure 502 includes a template layer 508 and a ferroelectric semiconductor layer 504 supported by the template layer 508. The template layer 508 may be composed of a GaN as shown. Alternatively or additionally, the template layer 508 may be composed of, or otherwise include, another semiconductor material, such as silicon, or a metal, such as molybdenum (Mo), Al, Ni, Cu, and Fe. As described herein, the ferroelectric semiconductor layer 504 is composed of, or otherwise includes, an alloy of a III-nitride material, such as ScAlN. In some cases, the ferroelectric semiconductor layer 504 may have a (0001) orientation. The orientation may vary in accordance with the epitaxial relationship between the template layer 508 and the ferroelectric semiconductor layer 504.

The alloy includes a Group IIIB element, such as Sc. The alloy may include one or more alternative or additional Group IIIB elements. In some cases, the III-nitride alloy is ScAlN. Alternative or additional III-nitride materials may be used, including, for instance, alloys of III-nitrides that include another group III element, such as Ga or In. Alternative or additional Group IIIB elements may be used, including, for instance, yttrium (Y) and lanthanum (La).

As shown in FIG. 5, the ferroelectric semiconductor layer 504 is in contact with the template layer 508 (e.g., GaN layer). The material composition of the template layer 508 may establish a lattice mismatch between the template layer 508 and the ferroelectric semiconductor layer 504. The lattice mismatch may, in turn, be used to tune or otherwise establish one or more properties or characteristics of the ferroelectric semiconductor layer 504. For instance, the coercive field of a ferroelectric nitride layer is a function of the lattice mismatch between the template layer 508 and the ferroelectric semiconductor layer 504. The coercive field can thus be modified (e.g., decreased or increased) in accordance with the amount or degree of lattice mismatch between the template layer 508 and the grown ferroelectric nitride layer 504.

The device 500 includes a dielectric layer 510 disposed adjacent to the ferroelectric semiconductor layer 504 and configured to establish a ferroelectric tunneling heterojunction with the ferroelectric semiconductor layer 504 and the template layer 508. For instance, the dielectric layer 510 and the ferroelectric semiconductor layer 504 may be sufficiently thin to establish the ferroelectric tunneling heterojunction. In some cases, the dielectric layer 510 is composed of, or otherwise includes, an oxide material. The oxide material may be a native oxide of the ferroelectric semiconductor material or a non-native oxide material.

As described herein, the ferroelectric semiconductor layer 504 and the dielectric layer 510 are configured such that the ferroelectric tunneling heterojunction exhibits a conductance level in accordance with a polarization of the ferroelectric semiconductor layer 504. For instance, the ferroelectric semiconductor layer 504 may have a thickness less than about 10 nm. The dielectric layer 510 may have a thickness less than 10 nm.

As described herein, the ferroelectric semiconductor layer 504 and the dielectric layer 510 are configured such that the ferroelectric tunneling heterojunction exhibits partial polarization switching. For instance, the partial polarization switching may establish a plurality of non-zero conductance levels in addition to an off state of the device 500.

The device 500 includes one or more electrodes or contacts 512, 514. In this example, the heterostructure 502 further includes a top or upper contact 512 or other electrode in contact with the dielectric layer 510, and a lower or bottom contact 514 on the template layer 508. The contacts 512, 514 may be composed of, or otherwise include, one or more metal layers. For example, the contacts 512, 514 may be composed of, or otherwise include, a metal stack including Ti and Au layers. For instance, the Ti layer may have a thickness of about 50 nm, and the Au layer may have a thickness of about 100 nm. One or both of the contacts 512, 514 may be configured as a circular or other pad (e.g., a diameter of 50 μm).

The device 500 further includes one or more control circuits 516 coupled to the ferroelectric tunneling heterojunction. The control circuit 516 may be coupled to the contacts 512, 514 and configured to apply read/write voltages across the ferroelectric tunneling heterojunction. In the example of FIG. 5, the control circuit 516 includes a driver circuit 518 configured to apply non-linear write voltage levels across the ferroelectric tunneling heterojunction to establish a plurality of polarization states of the ferroelectric tunneling heterojunction. As described herein, the plurality of polarization states may include multiple intermediate polarization states.

In this case, the template layer 508 is in contact with the substrate 506. Alternatively, one or more layers or structures are disposed between the template layer 508 and the substrate 506.

In some cases, the ferroelectric semiconductor layer 504 has an atomically smooth surface. The terms “atomically smooth” may be used herein in connection with layers of a heterostructure to indicate a layer having a surface roughness (e.g., a root mean square, or RMS, roughness) less than or on the order of 1 nm. In some cases, the RMS roughness of such atomically smooth layers is less than 1% of the thickness of the layer. The surface roughness may vary in accordance with the growth conditions, parameters, and other aspects of the fabrication processes described and/or referenced herein and/or other processes.

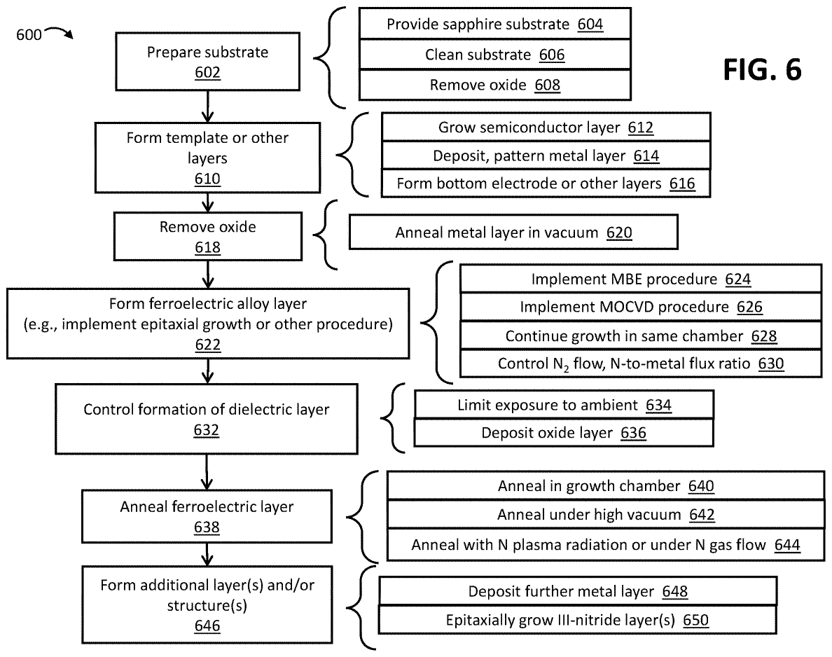

FIG. 6 depicts a method 600 of fabricating a device having a ferroelectric tunneling heterojunction in accordance with one example. As described herein, the ferroelectric tunneling heterojunction includes a ferroelectric semiconductor layer (e.g., single crystalline wurtzite structure) of an alloy of a III-nitride material with scandium and/or another IIIB element incorporated therein. As described herein, the method 600 is configured such that the ferroelectric semiconductor layer may be grown on a variety of different template layers to form a heterostructure. The method 600 may be used to fabricate the examples of ferroelectric tunneling junctions and heterostructures described herein or other nitride-based ferroelectric devices.

The method 600 may begin with an act 602 in which a substrate is prepared and/or otherwise provided. In some cases, the act 602 includes providing a sapphire substrate in an act 604. The substrate may be patterned or otherwise processed to configure the substrate to reduce defect formation in subsequently grown layers of the heterostructure and/or otherwise improve material quality therein. Such processing may also facilitate the formation of a different regions of the heterostructure.

Alternative or additional substrate materials may be used, including, for instance, silicon, bulk GaN, bulk AIN, or other semiconductor material. Still other materials may be used, including, for instance, silicon carbide. In still other cases, a metal substrate may be used. For instance, the metal substrate may be composed of, or otherwise include, Al, Pt, and/or Mo.

The substrate may be cleaned in an act 606. In some cases, a native or other oxide layer may be removed from a substrate surface in an act 608. The oxide removal may include multiple steps, including, for instance, an etch step and an annealing step.

Additional or alternative processing may be implemented in other cases, including, for instance, doping or deposition procedures. The substrate thus may or may not have a uniform composition. The substrate may be a uniform or composite structure. Any number of layers or structures may be deposited on the substrate prior to the implementation of the acts described below.

The method 600 may include an act 610, in which one or more template or other layers are formed or otherwise provided. The template layer is supported by the substrate. In some cases, the template layer is in contact with the substrate. In other cases, one or more buffer or other layers or structures are disposed between the template layer and the substrate. As described herein, the template layer may be composed of, or otherwise include, a metal or a semiconductor material.

In the example of FIG. 6, the act 610 includes an act 612 in which the template layer is grown. For instance, an n-doped GaN layer may be grown via MBE. Alternatively or additionally, a metal layer may be deposited and patterned in an act 614. A wide variety of deposition procedures may be used.

The act 610 may include the deposition or other formation of one or more other layers or structures. For example, a bottom electrode or other conductive structure may be formed in an act 616. The act 616 may be implemented in parallel with (e.g., as part of) the act 612. The number and other characteristics of the conductive structures may vary in accordance with the configuration of the device (e.g., the number of terminals).

In some cases, the method 600 includes an act 618 in which a surface treatment procedure is implemented to remove oxide from a surface of a metal template layer. In some cases, the act 618 includes annealing a polycrystalline metal layer in a vacuum in an act 620. The temperature of the annealing may vary, e.g., with the composition of the metal layer. The annealing may also improve the surface roughness of the metal layer. In some cases, the annealing may be implemented in the MBE growth chamber to remove the native oxide (e.g., MoO₃) and obtain a fresh, clean, and atomically smooth Mo(011) surface. The oxide may be removed in additional or alternative ways to achieve a highly ordered atomically smooth surface. For instance, the oxide may be removed via an etching procedure using, e.g., an acid solution, such as hydrochloric acid (HCl) or buffered hydrofluoric acid (BHF).

A non-sputtered, epitaxial growth procedure is implemented in an act 622 to form a single-crystalline ferroelectric semiconductor layer supported by, and in contact with, the polycrystalline metal layer. As described herein, the single-crystalline semiconductor layer is composed of, or otherwise includes, an alloy of a III-nitride material. The non-sputtered, epitaxial growth procedure is configured to incorporate a group IIIB element into the alloy of the III-nitride material.

As described herein, the III-nitride alloy layer has a wurtzite structure. For instance, the III-nitride material may be AlN. Additional or alternative III-nitride materials may be used, including, for instance, gallium nitride (GaN), indium nitride (InN), and their alloys. As also described herein, the epitaxial growth procedure is configured to incorporate scandium and/or another group IIIB element into the alloy of the III-nitride material. The alloy may thus be ScAlN, for example. In some cases, the act 622 includes an act 624 in which an MBE procedure is implemented. In other cases, an MOCVD or other non-sputtered epitaxial growth procedure is implemented in an act 626.

In some cases, the act 622 may include an act 628 in which the single-crystalline semiconductor layer is grown in a chamber in which the growth of the template layer and/or annealing procedure for the surface treatment of the act 618 is implemented. As a result, the substrate may remain within, e.g., is not removed from, the epitaxial growth chamber between formation of the template layer and the ferroelectric semiconductor layer.

The ferroelectric semiconductor layer may be grown on the template layer using a wide growth window. For example, in some cases, the growth window may be compatible with CMOS fabrication processes.

The growth temperature may be at a level such that the wurtzite structure exhibits a breakdown field strength greater than a ferroelectric coercive field strength of the wurtzite structure. Ferroelectric switching and other ferroelectric behavior may thus be achieved.

The growth temperature may be at a level lower than what would be expected given the III-nitride material. In some examples, the growth temperature level is significantly less than the temperature at which the III-nitride material would typically be grown. For instance, the growth temperature level may be such that attempts to grow a structure composed of the III-nitride material (i.e., without scandium) at the growth temperature level would not be worthwhile. The resulting structure would be of such poor quality (e.g., possess far too many defects) to be useful. Growth of a single-crystalline scandium-including alloy (e.g., a monocrystalline layer of the alloy) at the growth temperature level may nonetheless be achieved. For example, in some cases, a ScAlN alloy may be epitaxially grown at a growth temperature of about 650 degrees Celsius despite that the corresponding (scandium-free) III-nitride material, AIN, is conventionally grown at much higher temperatures, e.g., about 1000 degrees Celsius. Conversely, attempts to grow AlN at about 650 degrees Celsius or lower would result in structures of such poor quality. In contrast, the epitaxially grown ScAlN layer grown at that low temperature is unexpectedly of high quality and good electrical properties.

Growth of the ScAlN layer at the conventional AIN growth temperature (and other temperatures above the upper bound) unexpectedly results in the formation of dislocations and/or other leakage paths in the ScAlN layer. With the leakage paths, the ScAlN layer has a breakdown field strength level too low (e.g., below the ferroelectric coercive field strength level). The layer accordingly does not exhibit ferroelectric behavior.

In some cases, the growth temperature may be about 650 degrees Celsius or less. The growth temperature may correspond with the temperature measured at a thermocouple in the growth chamber. The growth temperature at the epitaxial surface may be slightly different. The growth temperature is accordingly approximated via the temperature measurement at the thermocouple.

The upper bound of the growth temperature range may vary in accordance with the alloy and/or the epitaxial growth technique. For instance, in other cases, the upper bound on the growth temperature may be higher, such as about 700 degrees Celsius, or about 750 degrees Celsius. In still other cases, the upper bound may be lower, including, for instance, about 550 degrees Celsius or about 600 degrees Celsius.

At each level within the above-described ranges of suitable growth temperatures, the resulting wurtzite structure is monocrystalline. The resulting wurtzite structure is monocrystalline to a degree not realizable via, for instance, sputtering-based procedures for forming ScAlN layers. Such procedures are only capable of producing structures with x-ray diffraction rocking curve line widths on the order of a few degrees at best. In contrast, the structures grown by the disclosed methods exhibit x-ray diffraction rocking curve line widths on the order of a few hundred arc-seconds or less, well over an order of magnitude less. In this manner, leakage current paths are minimized or otherwise sufficiently reduced so that the resulting wurtzite structure has a suitably high breakdown field strength level, e.g., sufficiently greater than the ferroelectric coercive field strength.

Additional or alternative differences in crystal quality may be used to distinguish between single-crystalline (or monocrystalline) and polycrystalline structures. As used herein, the term “polycrystalline” refers to structures having multiple domains with in-plane rotation. As used herein, the terms “monocrystalline” or “single crystalline” refer to structures having unique domains without in-plane rotation, e.g., as indicated by x-ray φ scans that have only one set of diffraction peaks.

Comparing the wurtzite structures of the layers grown by MBE or other non-sputtered techniques (e.g., MOCVD or HVPE) with sputtering deposition techniques, the microstructure of the former techniques is more uniform with highly ordered stacking sequence of atoms. In sputter deposited layers, domains with cubic phase or domains with in-plane mis-orientation are readily observed. The existence of these mis-aligned domains suppresses the complete switching of polarization, and further results in the fast loss of polarization during fatigue testing. Regarding phase purity, the highly crystallographic orientation of layers grown by MBE or other non-sputtered techniques exhibits more repeatable ferroelectric switching, which is useful in a number of device applications.

In some cases, the wurtzite structure of the ferroelectric semiconductor layer is metal-polar. In other cases, the single-crystalline semiconductor may be nitrogen-polar (N-polar).

In some cases, the epitaxial growth procedure is implemented under a nitrogen-rich condition. For example, the nitrogen-to-metal flux ratio may be set in an act 630 in which the nitrogen flow is controlled. In some cases, the unbalanced flux ratio may be set to a highly or extremely nitrogen (N)-rich condition, such as a N-to-metal flux ratio of 2-to-1 or higher.

Control of the flux ratio between metal and nitrogen sources may be useful for improving the material quality of the ScAlN or other III-nitride alloy layer. As described herein, the N-rich growth conditions may be useful in connection with the growth of ScAlN to avoid Sc-Al intermetallic, Sc₃AlN perovskite phase formation, and/or other defects.

The method 600 includes an act 632 in which the formation of a dielectric layer adjacent the ferroelectric semiconductor layer is controlled. As described herein, the dielectric layer is configured to establish a ferroelectric tunneling heterojunction with the ferroelectric semiconductor layer and the template layer. The dielectric layer may be formed adjacent to a side of the ferroelectric layer opposite the template layer.

In some cases, the act 632 includes an act 634 in which controlling the formation of the dielectric layer includes limiting exposure to an ambient such that a native oxide layer is grown to a thickness sufficiently thin to establish the ferroelectric tunneling heterojunction. For instance, the exposure may be limited to a time period such that a thickness of a native oxide layer is no greater than about 10 nm. In some cases, the act 634 may be configured to limit the time period during which the ferroelectric semiconductor layer is exposed to the ambient. For instance, the time period may be less than 24 hours. Other time periods may be used. Alternatively or additionally, the ambient may be controlled. For instance, in some cases, the ambient is established by, or otherwise includes, a nitrogen-purged container.

Alternatively or additionally, the act 632 includes an act 636 in which controlling the formation of the dielectric layer includes depositing an oxide layer (or other dielectric layer) sufficiently thin to establish the ferroelectric tunneling heterojunction. A variety of non-native oxide materials may be deposited, including, for instance, silicon dioxide, aluminum oxide, hafnium oxide, scandium oxide, etc. In still other cases, a non-oxide dielectric material such as silicon nitride or aluminum nitride may be deposited.

In some cases, the single-crystalline semiconductor layer may then be annealed in an act 638. The annealing may be implemented at a temperature greater than the growth temperature. In some cases, the annealing temperature falls in a range from about 700 Celsius to about 1500 degrees Celsius. Examples of films prepared with such annealing exhibited stable polarization switching with further reduced leakage current relative to non-annealed films. Film or device uniformity was also improved via the annealing, thereby further improving the polarization switching behavior of the ferroelectric Sc-III-N alloys. The underlying mechanism for the improved performance and uniformity with annealing is attributed to the reduced threading dislocation density and defect density, which usually act as electric leakage paths. Such usefulness of the post-growth annealing is realized despite past concerns that high processing temperatures can lead to a loss of ferroelectricity.

Such post-growth high-temperature annealing of ScAlN may be performed in-situ in the same growth chamber (e.g., the same MBE chamber) in an act 640. In other cases, the annealing is performed ex-situ in a chamber directed to annealing procedures.

The annealing process may be implemented under high vacuum in an act 642 (e.g., in-situ in the growth chamber). In other cases, the annealing may be implemented either with nitrogen plasma radiation or under nitrogen gas flow in an act 644.

The above-described annealing procedure may be implemented in connection with films grown under any of the above-described growth conditions. For instance, the annealing procedure may be implemented after growth under slightly to moderately N-rich conditions at a growth temperature below about 650 degrees Celsius. The annealing procedure may also be implemented after growth under unbalanced flux ratios (e.g., N-rich or extreme N-rich conditions) at growth temperatures above about 650 degrees Celsius.

The method 600 may include an act 646 in which one or more layers are formed after growth of the heterostructure. For instance, one or more metal layers or other conductive structures may be deposited and patterned in an act 648. In some cases, the conductive structure is configured as an upper or top contact (or component thereof). In other cases, the conductive structure may be a gate. Alternatively or additionally, one or more III-nitride (e.g., GaN or AIGaN) or other semiconductor layers may be epitaxially grown in an act 650. The act 650 may be implemented in the same epitaxial growth chamber used to grow the wurtzite structure.

In one example, after the ScAlN/GaN heterostructure was cleaned in acetone, methanol, and deionized water (e.g., with ultrasonic for 5 min in each step), photolithography was performed to pattern the sample surface, after which a 300-nm-thick SiO₂ layer was deposited by e-beam evaporation, and windows for contacts were opened via lift-off. A second mask was used to define the top and bottom electrodes. The metal stack (e.g., 50 nm Ti and 100 nm Au) was then deposited by e-beam evaporation and released by lift-off in hot acetone.

The method 600 may include fewer, additional, or alternative acts. For example, one or more acts may be directed to forming other structures or regions of the device that includes the heterostructure. The nature of the regions or structures may vary in accordance with the nature of the device. In another example, the method 600 does not include an act 610 in which a buffer layer is grown or otherwise formed, or the act 618 in which an oxide is removed from the template layer.

The order of the acts of the method 600 may differ from the example shown in FIG. 6. For example, contacts and/or other structures formed in the act 610 may be implemented after the growth of the ferroelectric layer.

A number of different types of devices may be fabricated by the method 600 of FIG. 6, and/or another method of fabricating a device having a ferroelectric tunneling heterojunction as described herein. For example, the ferroelectric tunneling heterojunction may be useful in various types of nonvolatile memory devices (e.g., FeRAM, FeFET, FTJ, and FeSFET devices), various types of reconfigurable electronic and other devices (e.g., Fe-HEMT, Fe-capacitor, and SAW devices), various types of photodetection, photovoltaic and optoelectronic devices (e.g., self-driven photodetector and solar cell devices), and various homojunction devices (e.g., devices that use a laterally distributed charge plate to tune the Fermi level in adjacent layers).

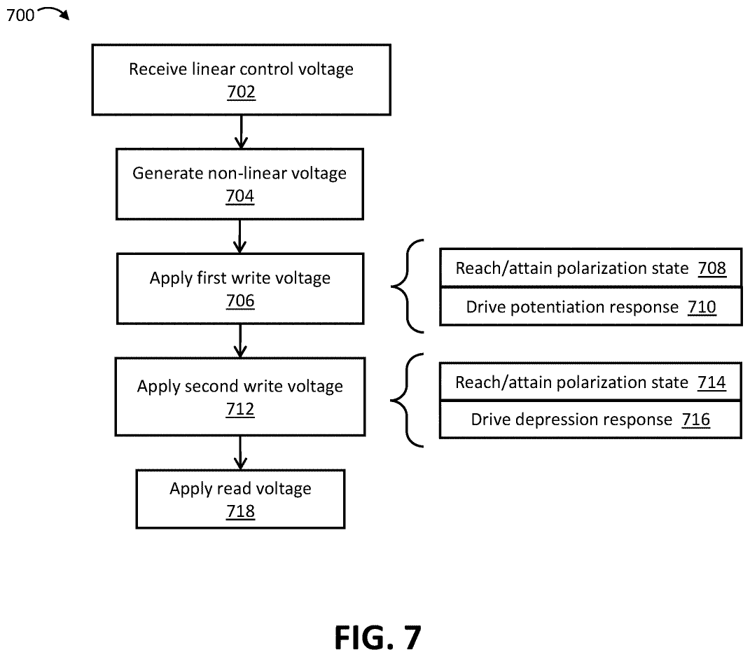

FIG. 7 depicts a method 700 of operating a device having a ferroelectric tunneling junction in accordance with one example. As described herein, the device has a plurality of polarization states. The number of polarization states is sufficiently large to support multiple intermediate polarization states. In some cases, the device is configured as a memristor or other memory device. The method 700 may be implemented by one of the memory devices described herein, or another device.

The method 700 may include receiving a linear control voltage in an act 702. The linear control voltage may be received by a driver or other control circuit as described herein. The control circuit may then generate in an act 704 a non-linear voltage based on the linear control voltage.

The non-linear voltage may then be applied to the device to programmatically switch the device to one of a number of polarization states as described herein. In the example of FIG. 7, the method 700 includes an act 706 in which a first write voltage is applied across the device. To that end, the first write voltage is at a level to switch the device to a new polarization state. The polarization state may be any one of the plurality of polarization states, including one of the intermediate polarization states of the device.

The act 706 may be part of one or more operational schemes. For instance, in one scheme, the write voltage is used in an act 708 to cause the device to reach or attain a selected one of the polarization states. For instance, in an eight-state (or three-bit control scheme), a new polarization state may be reached by switching from any one of the eight polarization states to one of the intermediate polarization states. In another scheme, the write voltage is used to drive a potentiation response in an act 710. Still other operational schemes may be used or implemented.

At some point, a new linear control voltage may be received and processed by the control circuit. A corresponding second write voltage may thus be applied across the device in an act 712. The second write voltage has a level to switch the device to any one of the other polarization states, including another one of the intermediate polarization states. For instance, the write voltage is used in an act 714 to cause the device to reach or attain a another selected one of the polarization states. In another operational scheme, the write voltage may be used to drive a depression response in an act 716.

The method 700 may be implemented to support computing in the analog regime using one or more of the disclosed ferroelectric resistive memory devices (e.g., ferroelectric resistive memory arrays). The use of the disclosed ferroelectric resistive memory devices can potentially alleviate the energy constraints and complexity/footprint challenges imposed by digital von Neumann systems. Furthermore, the use of the disclosed ferroelectric resistive memory devices can avoid limitations imposed by either low ON/OFF ratios/imprint or limited compatibility with mainstream semiconductors. Instead, the disclosed devices support ferroelectric and analog resistive switching. The epitaxial nitride heterojunctions having ultrathin (e.g., thickness of about 5 nm) nitride ferroelectric layers of the disclosed devices have the capability of bridging the gap between performance and compatibility. As described herein, high ON/OFF ratios (up to 10⁵), high uniformity, good retention (<20% variation after >10⁵ s) and cycling endurance (>10⁴) were simultaneously demonstrated in example metal/oxide/nitride ferroelectric junctions.

The method 700 may be implemented to provide programmability to enable multistate operation and linear analogue computing as well as image processing. For instance, the method 700 may be implemented to support classification via a neural network. The non-volatile multi-level programmability and analog computing capability of the disclosed devices support these and other advanced memory/computing architectures.

The term “about” is used herein in a manner to include deviations from a specified value that would be understood by one of ordinary skill in the art to effectively be the same as the specified value due to, for instance, the absence of appreciable, detectable, or otherwise effective difference in operation, outcome, characteristic, or other aspect of the disclosed methods and devices.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

1. A device comprising:
a substrate;
a template layer supported by the substrate;
a ferroelectric semiconductor layer adjacent to the template layer, the ferroelectric semiconductor layer comprising an alloy of a III-nitride material and a Group III-B element; and
a dielectric layer disposed adjacent to the ferroelectric semiconductor layer and configured to establish a ferroelectric tunneling heterojunction with the ferroelectric semiconductor layer and the template layer;
wherein the ferroelectric semiconductor layer and the dielectric layer are configured such that the ferroelectric tunneling heterojunction exhibits a conductance level in accordance with a polarization of the ferroelectric semiconductor layer.

2. The device of claim 1, wherein the dielectric layer and the ferroelectric semiconductor layer are sufficiently thin to establish the ferroelectric tunneling heterojunction.

3. The device of claim 1, wherein the ferroelectric semiconductor layer has a thickness less than about 10 nm.

4. The device of claim 1, wherein the dielectric layer has a thickness less than about 10 nm.

5. The device of claim 1, wherein the ferroelectric semiconductor layer and the dielectric layer are configured such that the ferroelectric tunneling heterojunction exhibits partial polarization switching.

6. The device of claim 5, wherein the partial polarization switching establishes a plurality of non-zero conductance levels in addition to an off state of the device.

7. The device of claim 1, wherein the dielectric layer comprises an oxide material.

8. The device of claim 7, wherein the oxide material is a non-native oxide of the ferroelectric semiconductor layer.

9. The device of claim 7, wherein the oxide material is a native oxide of the ferroelectric semiconductor layer.

10. The device of claim 1, wherein the dielectric layer comprises a non-oxide material.

11. The device of claim 1, wherein the ferroelectric semiconductor layer is in contact with the template layer.

12. The device of claim 1, further comprising a driver circuit coupled to the ferroelectric tunneling heterojunction and configured to apply non-linear write voltage levels across the ferroelectric tunneling heterojunction to establish a plurality of polarization states of the ferroelectric tunneling heterojunction, the plurality of polarization states comprising multiple intermediate polarization states.

13. A method of fabricating a device, the method comprising:
providing a substrate;
forming a template layer supported by the substrate;
implementing a non-sputtered, epitaxial growth procedure to form a ferroelectric semiconductor layer, the ferroelectric semiconductor layer being supported by, and in contact with, the template layer, the ferroelectric semiconductor layer comprising an alloy of a III-nitride material, the non-sputtered, epitaxial growth procedure being configured to incorporate a group IIIB element into the alloy of the III-nitride material; and
controlling formation of a dielectric layer adjacent the ferroelectric semiconductor layer, the dielectric layer being disposed and configured to establish a ferroelectric tunneling heterojunction with the ferroelectric semiconductor layer and the template layer.

14. The method of claim 13, wherein controlling formation of the dielectric layer comprises depositing an oxide layer having a thickness sufficiently thin to establish the ferroelectric tunneling heterojunction.

15. The method of claim 13, wherein controlling formation of the dielectric layer comprises limiting exposure to an ambient such that a native oxide layer is grown to a thickness sufficiently thin to establish the ferroelectric tunneling heterojunction.

16. The method of claim 13, wherein controlling formation of the dielectric layer comprises depositing a non-oxide layer having a thickness sufficiently thin to establish the ferroelectric tunneling heterojunction.

17. The method of claim 13, wherein the non-sputtered, epitaxial growth procedure is configured such that the ferroelectric semiconductor layer has a thickness of less than about 10 nm.

18. The method of claim 13, further comprising annealing the ferroelectric semiconductor layer.

19. The method of claim 13, wherein the non-sputtered, epitaxial growth procedure is implemented under a nitrogen-rich condition.

20-23. (canceled)
